(19) United States
(12) Patent Application Publication
(10) Pub. No.: US 2015/0211836 A1
(43) Pub. Date: Jul. 30, 2015

(54) Systems and Methods for Generating Backside Substrate Texture Maps for Determining Adjustments for Front Side Patterning

(71) Applicant: Tokyo Electron Limited, Tokyo (JP)

(72) Inventors: Anton J. deVilliers, Clifton Park, NY (US); Todd A. Mathews, Ballston Lake, NY (US); Rodney Lee Robison, East Berne, NY (US)

(21) Appl. No.: 14/604,393

(22) Filed: Jan. 23, 2015

Related U.S. Application Data
(60) Provisional application No. 61/931,555, filed on Jan. 24, 2014.

(51) Int. Cl. G01B 5/28; H01L 21/66; H01L 21/68; H01L 21/67; H01L 21/683

(52) U.S. Cl. CPC G01B 5/28; H01L 21/67288; H01L 21/6831; H01L 21/68; H01L 22/12

(57) ABSTRACT

Techniques disclosed herein a method and system for generating texture maps for the backside of a substrate. The texture maps may be used to determine process adjustments (e.g., depth of focus) for subsequent processing of the front side of the substrate.

### BACKGROUND OF THE INVENTION

Shrinking device dimensions place aggressive demands on defect detection metrology. As device density and critical dimensions (CD) uniformity requirements become more stringent, the maximum potential of lithography can be exploited when the quality of the incoming wafer is not compromised. Nearly all the processes in a wafer fab can cause backside contamination. In smaller device features, the lithography focus spot problem is exacerbated because of small depth of focus (DOF) and tighter CD. Accordingly, techniques to account for focus spot problems may be desirable.

### SUMMARY

Generally, backside substrate surface roughness and irregularity may be mapped in order to meet the focusing-threshold and the exposure challenges. Surface roughness may also include backside defects (particles or scratches) that can create local distortions of the wafer, causing the DOF issues that result in lithography focus spots. Backside surface irregularity may defined and mapped in order to minimize the defects due to depth of focus, light scattering, overlay etc. For example, a surface roughness sensor may be able to quantify surface roughness for localized areas on the substrate. In combination with a location component that determines the location of the localized areas on the substrate, a texture mapping component may generate a texture map that highlights which portions of the substrate are likely to cause DOF issues during subsequent patterning of the front side of the substrate. An adjustment component may use the texture map data to determine any subsequent patterning process adjustments that may eliminate or minimize the DOF issues.

In one embodiment, the surface roughness sensor may include an acoustic stylus to detect the amplitude and frequency of backside substrate features or irregularities. The acoustic stylus may generate an audio signal that is recorded and correlated with the location of the substrate and the stylus. The amplitude and frequency of the audio signal may be used to determine the size and scope of the surface roughness or irregularities. The acoustic stylus may be in contact with the rotating substrate as it is moved across the substrate. The acoustic stylus may include a contact element that makes contact with the substrate without causing substantive damage to the substrate. The contact element may be coupled to a piezoelectric component that may generate an electrical signal when force is applied to the contact element. The electrical signal may be representative of the backside surface topography, such that the amplitude and/or frequency of the backside surface roughness may be determined. In other embodiments, the contact element may be magnetically coupled to one or more magnets that generate an electrical signature when force is applied to the contact element.

In another embodiment of a texture mapping system, the backside of the substrate may be secured to a rotating chuck that may rotate the substrate while two or more surface roughness sensors (e.g., acoustic stylus) that may be moved across the backside surface of the substrate. The system may detect the physical characteristics of the backside surface features and determine the location of those features. The surface roughness data may be used to adjust front side processing conditions to improve front side processing performance. In one specific example, the planarity or flatness of the front side surface may be impacted by the backside surface roughness. When the backside of the substrate is placed on a processing chuck, the backside surface roughness may cause localized or regional variations in front surface planarity that may increase process non-uniformity across the front side. A higher degree surface roughness or non-uniformity of the backside surface may cause the substrate to bend or deform.

In one embodiment, the texture mapping system detects the amplitude and/or frequencies of the backside features that may be used to quantify surface roughness. The system may use a substrate chuck to secure and rotate (e.g., <60 rpm) the substrate, such that a surface roughness sensor can move across the backside of the substrate and detect the surface roughness characteristics of the backside. The surface roughness sensor may provide the surface roughness information or signal to a texture map component that may generate a texture map using the surface roughness information and the known location of the surface roughness sensor relative to the substrate during data collection. The surface roughness sensor may or may not contact the surface of the substrate to collect the surface roughness information.

In one embodiment, the surface roughness sensor may include a contact element that can make contact with the backside surface of the substrate. The contact element may include, but is not limited to a mechanical stylus that may be in contact with the backside as the substrate. The contact element may maintain contact with the substrate during the substrate rotation and/or when a movement arm moves the profile sensor across the substrate. The substrate rotation and the surface roughness sensor movement may enable the texture mapping system to collect surface roughness data across the substrate. The contact element may be connected to a signal transducer or detection component that may generate an electrical signal that is representative of the amplitude and/or frequency of the backside features of the substrate. In one specific embodiment, the detection component may include a piezoelectric material that may generate an electrical signal that may be correlated to the amount of pressure or force applied to the contact element. The information encoded within the electrical signal may provide an indication of amplitude/frequency or topography of the backside features of the substrate.

In another embodiment, the surface roughness sensor may include two or more contact elements that may contract the backside of the same substrate. The additional sensors may increase the amount of data collected and provide a higher resolution texture map of the surface roughness and/or decrease the amount of time needed to collect the data. In this instance, the texture map component may collect and analyze data from multiple surface roughness sensors concurrently collecting data at different locations across the substrate.

In one embodiment, the texture map may include surface roughness values assigned to coordinate locations on the substrate that may be make offset adjustments for a patterning process on the front side of the substrate. For example, changes of front side topography may be caused the backside surface roughness and the texture map may be used to compensate for those topography changes. The offset adjustments may include, but are not limited to, depth of focus adjustments, overlay adjustments, or a combination thereof. In this way, the subsequent patterning process may be adjusted to account for topography differences across the substrate that may be related to backside surface roughness.

### BRIEF DESCRIPTION OF THE DRAWINGS

The advantages of the technology described above, together with further advantages, may be better understood by referring to the following description taken in conjunction with the accompanying drawings. In the drawings, like reference characters generally refer to the same parts throughout the different views. The drawings are not necessarily to scale, emphasis instead generally being placed upon illustrating the principles of the technology.

FIG. 1 illustrates a schematic of a texture mapping system and a representative embodiment for the texture mapping system.

FIG. 2 illustrates a representative embodiment of a profile sensor interacting with the backside of a substrate.

FIG. 3A illustrates a schematic of a sensor measurement point and path in a polar coordinate system.

FIG. 3B illustrates a schematic of a sensor measurement point and radial path that is converted from polar coordinates to Cartesian coordinates.

FIG. 3C illustrates a schematic of a sensor measurement point and radial path that is converted from polar coordinates to Cartesian coordinates.

FIG. 4 illustrates an embodiment of a texture map that highlights amplitudes and locations of surface roughness values on a substrate.

FIG. 5 illustrates a flow diagram for method of using the texture mapping system.

### DETAILED DESCRIPTION

Although the present invention will be described with reference to the embodiments shown in the drawings, it should be understood that the present invention can be embodied in many alternate forms of embodiments. In addition, any suitable size, shape or type of elements or materials could be used.

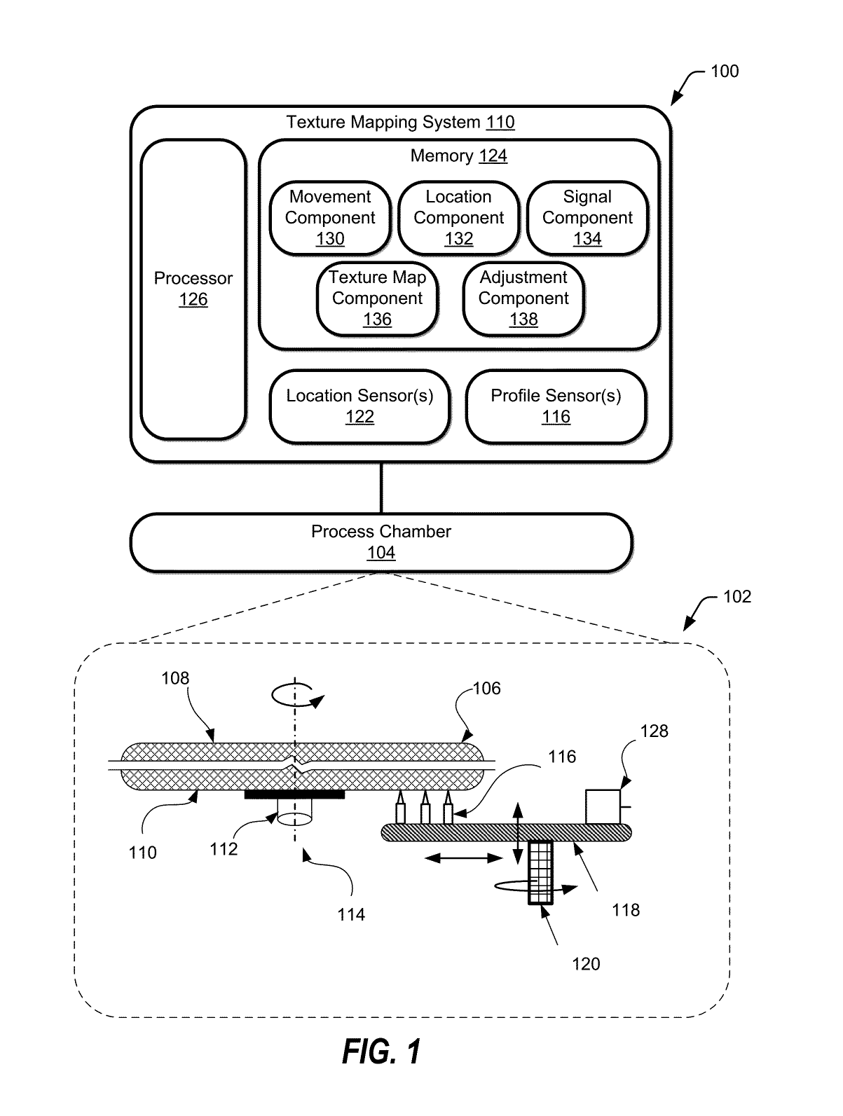

FIG. 1 illustrates a schematic of a texture mapping system 100 and a representative embodiment 102 of a portion of the texture mapping system 100 inside a process chamber 104. The texture mapping system 100 may be used to detect and map the surface roughness, topography, or planarity of the back side of the substrate 106. In one embodiment, the substrate 106 may be a work piece that may be used to manufacture electronic devices (e.g., memory, processor, display) by applying and patterning films on the front side 108 surface of the substrate 106. The substrate 106 may include, but is not limited to, silicon wafers that may have a front side 108 surface and a backside 110 surface that is opposite the front side 108 surface and the surfaces may also be parallel to each other.

Typically, the electronic devices are manufactured on the front side 108 of the substrate 106. The backside 110 of the substrate 106 may be used to support or secure the substrate 106 during film deposition and patterning. As electronic device dimensions continue to shrink, the impact of backside topography or surface roughness on front side 108 patterning has increased. Patterning an image on the front side 108 may be distorted due to surface non-uniformity caused by backside 110 surface roughness across the substrate 106 and/or at localized regions of the substrate 106. However, the non-uniformity may be compensated for during the patterning process. But, the degree of that compensation may be dependent upon knowing the location and magnitude of the non-uniformity. The texture mapping system 100 may generate a texture map or table that may be used compensate for non-uniformity induced by the backside 110 of the substrate 106. The texture mapping may be done in a non-destructive manner and have minimal, if any, impact to the front side 108. The texture mapping system 100 may be incorporated into the processing chamber 104 or as a stand-alone chamber within a piece of equipment. In another embodiment (not shown), the texture mapping system 100 may be a stand-alone tool that generates texture maps and does not provide subsequent front side 108 processing for the substrate 106.

The texture mapping system 100 may include hardware, firmware, software, or combination thereof to collect and analyze data, control the substrate 106 and movement arm 118, to generate a texture map (not shown), and to determine front side 108 locations that may be selected for front side 108 processing adjustments. The FIG. 1 embodiment is provided for illustrative purposes and is not intended to limit the scope of the claims. Persons of ordinary skill in the art may use any combination of hardware, firmware, or software to implement the techniques described herein.

In the FIG. 1 embodiment, the substrate 106 may be placed on and secured to a substrate chuck 112 via electrostatic or pneumatic techniques known in the art. The substrate chuck 112 may be rotated around a central axis 114 up to a speed of no more than 100 rpm. However, in other embodiments, the rotation speed may be between 5 rpm and 60 rpm. One or more profile sensors 116 (e.g., surface roughness sensor) may be moved across the backside 110 using a movement arm 118 that may be moved laterally, as indicated by the arrows, or pivoted around a counterbalance component 120, such that the profile sensors 116 may maintain contact with the substrate 106. In one embodiment, the movement arm 118 may be moved laterally as the substrate 106 is rotating to collect amplitude and frequency data on the backside 100 features. However, the movement arm 118 may also rotate around the counterbalance component 120 to sweep across the rotating or a non-rotating substrate 106. In one specific embodiment, the rotation speed may vary as the movement arm moves closer to the center of the substrate 106. For example, the rotation speed may increase as the movement arm approaches the center of the substrate 106. The rotation speed may vary based, at least in part, on the lateral resolution and/or vertical resolution of the profile sensors 116. As the profile sensor 116 resolution increases the rotation speed may decrease to enable proper sampling of the backside features.

The movement arm 118 may be coupled to mechanical, electrical, or pneumatic actuators that may be used to position the profile sensors 116 near or in contact with the substrate 106. In one embodiment, the profile sensor 116 may include a contact element that may be a stylus that is shaped small enough to have a lateral resolution down to 30 nm and a vertical resolution down to 0.1 nm. As shown in FIG. 1, the stylus may have a pointed tip that may be coupled to a detection component or transducer that generates an electrical signal based on the movement or vibration of the stylus as it moves across the substrate 106. In one embodiment, the detection component may include a piezoelectric material that generates the profile signal in response to the pressure applied by the contact element. In other embodiments (not shown), the profile sensors 116 may use non-contact detection techniques to collect texture map data.

In one embodiment, the sampling of the backside 110 surface may be done to target specific locations without continuously sampling the surface. For example, the system 100 may be directed to sample specific portions of the substrate 106. The pivoting up and down of the movement arm 118 pivoting may enable the system 100 to select specific locations for sampling for limited durations and moving to another sample location without being in constant contact with the substrate 106. For example, the system 100 may sample one region near the center of the substrate 106 and then pivot to disengage from the substrate and move to second sample location (e.g., edge of the substrate) and pivot to make contact with the backside 110 surface again. This sampling technique may be reduce backside contact (e.g., particle generation) or may be used for quality control purposes prior to subsequent processing. Based on the initial results, the substrate 106 may be selected for additional sampling or backside 110 conditioning prior to subsequent processing.

Location sensors 122 may be positioned, as needed, in or around the movement arm 118 and/or substrate 106 to monitor the location of the substrate 106 and/or movement arm 118 and profile sensors 116. The location sensors 122 may be used to generate location coordinates that correspond to the portions of the substrate 106 that are scanned by the profile sensors 116. The location information may be associated with portions of the profile signal, such that the amplitude and/or frequency of the profile signal may be mapped to specific portions of the substrate 106. The location sensors 122 may incorporate a variety of detection techniques that may include, but are not limited to, optical, electrical, mechanical, or combination thereof.

In the FIG. 1 embodiment, the location sensors 122 and/or profile sensors 116 may be integrated with a computer processing device (e.g., memory 124, processor 126) using an electrical conduit 128. The computer processing device may include a variety of components that may monitor, control, and/or analyze the electrical signals from the processing chamber 104. Although the components are shown as discrete elements, the features and capabilities may be implemented in different ways as understood by person of ordinary skill in the art.

The movement component 130 may control and monitor the movement of the substrate chuck 112 and the movement arm 118, such that the profile sensors 116 may be placed in contact with the backside 110 surface when the substrate 106 may or may not be rotated. The movement component 130 may control where the profile sensors 116 are positioned on the backside 110 surface and the pressure applied to the backside 110 by the profile sensors 116. For example, the movement component 130 may position the movement arm 118 to cover the maximum surface area based on the number of profile sensors 116 and the size of the substrate 106. In the FIG. 1 embodiment, only three profile sensors 116 and one movement arm 118 are shown, but the texture mapping system 100 may use one or more profile sensors 116 and one or more movement arms 118 to collect surface roughness data.

In conjunction with the movement component 130, the location component 132 may detect and monitor the locations of the profile sensors 116 relative to the substrate 106 in the x, y, z planes under the Cartesian coordinate system or radius and angles under a polar (e.g., r, θ) or spherical (e.g., r, θ, φ) coordinate system. The location component 132 may determine the coordinate location for the points of contact between the backside 110 surface and the contact element.

The signal component 134 may monitor and track the signal from the detection component and assign a value to the coordinate locations determined by the location component 132. For example, when the profiles sensor(s) 116 comes into contact with the roughness the backside 110 surface, the change in vibration/frequency may be recorded by the detection component(s) (e.g., piezoelectric sensors). The signal component 134 may then assign a amplitude and/or frequency value to the location coordinate for the contact points determined by the location component 132. The combination of the location information and the vibration/frequency information may be used to generate a texture map of the backside 110 surface.

The texture map component 136 may identify portions of the backside 110 surface that may impact the planarity of the front side 108 surface when the substrate 106 is placed on the back side 110 surface during subsequent patterning. By way of example, and not limitation, the localized thickness variations on the backside 110 surface may cause localized regions of the substrate 106 to bend or deform at those locations causing the front side 108 surface to have lower planarity or uniformity. The localized regions may impact the patterning results relative to adjacent and/or more uniform areas. The patterning process conditions may be able to account for a portion of the variation, however, in some instances; the variation may be remedied by a site or location specific process condition change or compensation. The texture map may also be used to identify non-uniformity on a broader scale than the localized regions. For example, adjacent regions may have the same or similar profile conditions, but the small changes may accumulate across the substrate, such that the different processing conditions may be needed at different locations across the substrate 106. The broader non-uniformity trends across the backside 110 surface may make one side of the substrate 106 higher in the z-direction or vertical direction. The texture map component 136 may analyze the surface roughness data and provide an indication on which locations may be compensated and how that compensation may change across the substrate 106.

In the multi-profile sensor 116 embodiment, the texture map component 136 may also stich together data from multiple profile sensors 116 to generate a texture map for the backside 110 surface. In this embodiment, the coordinates from the location component 132 may be used to piece together adjacent profile sensor 116 data together to generate a texture map of the backside 110 surface. In one embodiment, the texture map component 136 may compare the coordinates (e.g., x, y) to determine which points are closest to each other and assign a relationship to the one or more pairs based on the relative location to each other. For example, when the distance between two or more points is within a threshold distance the assignment indicates whether the profile data are adjacent and/or overlap or whether they may be combined with each other in a logical manner. The texture map component 136 may use the relationship to stitch together, combine, or align those data points with each other within the texture map. One embodiment of the texture map is illustrated in FIG. 6.

The texture map or table may be provided to an adjustment component 138 that may determine the amount of front side 108 processing compensation that may be used to minimize the impact of the backside 110 surface roughness. In one embodiment, the adjustment component 138 may determine which backside features are likely to impact front side 108 processing. Those identified backside 110 surface locations may be correlated with front side 108 locations and an adjustment value or process condition may be associated with the front side 108 location(s). The front side 110 process adjustments may be provided to a patterning tool (not shown). In one embodiment, the height differences on the front side 108 of the substrate may impact the quality of images being patterned using optical equipment. Image resolution quality may be lower from site-to-site based on the height differences on the front side 108 of the substrate 106. One way to account for the height differences may be to adjust the depth of focus (DOF) of the patterned image, such that site-to-site image resolution is more uniform across the substrate 106. The DOF may be adjusted higher or lower depending on the height differences between two or more locations on the substrate 106. The DOF may be adjusted higher for relatively higher regions on the texture map or lowered for relatively lower regions on the texture map. In another embodiment, the adjustment component 138 may calculate process adjustments (e.g., overlay adjustments) that correspond to coordinates or regions on the texture map. The overlay adjustments may adjust the translation, scaling, rotation, and/or orthogonality of the front side imaging to the underlying pattern. The translation compensation by the patterning tool may include adjusting the front side image in the x, y, and/or z directions. The rotation compensation may include rotating the front side image around the z-axis of the image or the substrate. The scaling compensation may be done by uniformly adjusting the size of the front side image. The orthogonal compensation may adjust the degree of perpendicularity of two or more lines to each other. In other embodiments, the adjustment component 138 may also adjust for exposure time and dose in view of the texture map, as needed by a person of ordinary skill in the art of photolithography.

In the FIG. 1 embodiment, the texture mapping system 100 may be implemented using a computer processor 126 that may include one or more processing cores and are configured to access and execute (at least in part) computer-readable instructions stored in the one or more memories. The one or more computer processors 126 may include, without limitation: a central processing unit (CPU), a digital signal processor (DSP), a reduced instruction set computer (RISC), a complex instruction set computer (CISC), a microprocessor, a microcontroller, a field programmable gate array (FPGA), or any combination thereof. The computer processor may also include a chipset(s) (not shown) for controlling communications between the components of the texture mapping system 100. In certain embodiments, the computer processors 126 may be based on Intel® architecture or ARM® architecture and the processor(s) and chipset may be from a family of Intel® processors and chipsets. The one or more computer processors may also include one or more application-specific integrated circuits (ASICs) or application-specific standard products (ASSPs) for handling specific data processing functions or tasks.

The memory 124 may include one or more tangible non-transitory computer-readable storage media (“CRSM”). In some embodiments, the one or more memories may include non-transitory media such as random access memory (“RAM”), flash RAM, magnetic media, optical media, solid state media, and so forth. The one or more memories may be volatile (in that information is retained while providing power) or non-volatile (in that information is retained without providing power). Additional embodiments may also be provided as a computer program product including a transitory machine-readable signal (in compressed or uncompressed form). Examples of machine-readable signals include, but are not limited to, signals carried by the Internet or other networks. For example, distribution of software via the Internet may include a transitory machine-readable signal. Additionally, the memory may store an operating system that includes a plurality of computer-executable instructions that may be implemented by the computer processor 126 to perform a variety of tasks to operate the texture mapping system 100.

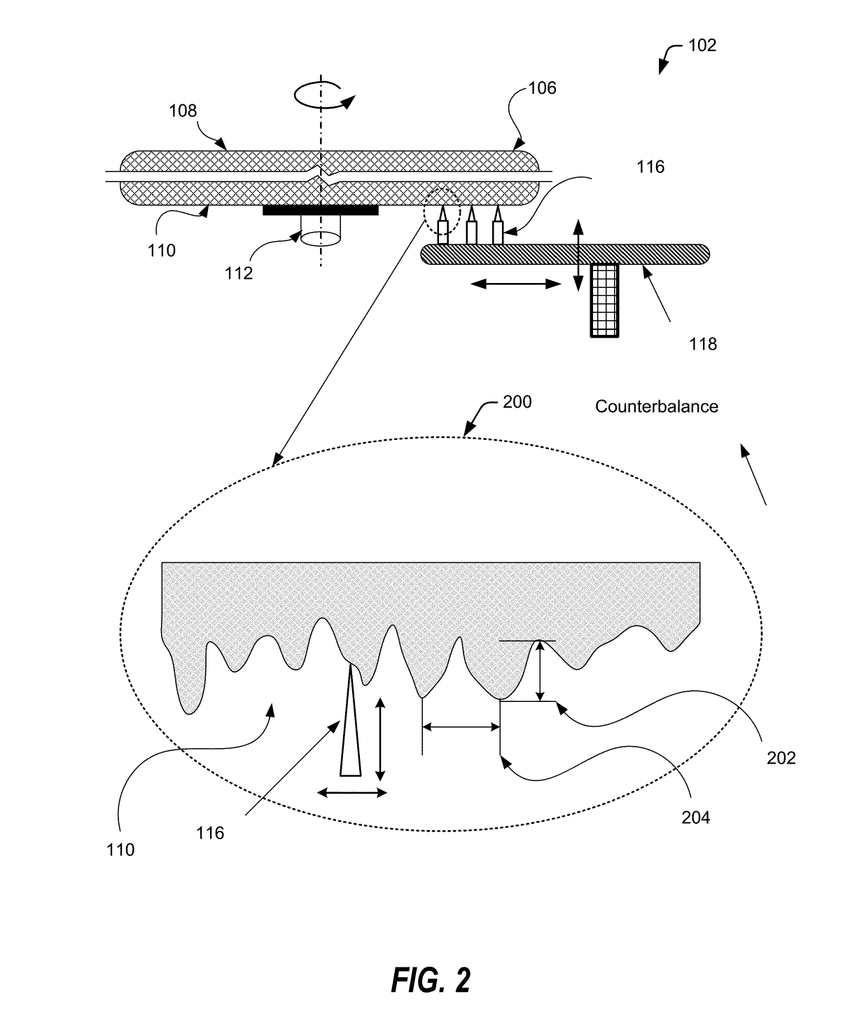

FIG. 2 illustrates a detailed view 200 of the profile sensor 116 interacting with the backside 110 of the substrate 106. The profile sensor 116 may move across the backside 110 feature and may vibrate/oscillate depending on the amplitude 202 and the period 204 of the backside 110 features. In one embodiment, the period 204 may be representative of the peak-to-peak distance between backside 110 features and the amplitude may be representative of the peak-to-valley distance of the backside 110 features.

The texture mapping system 100 may use changes in amplitude 202, period 204, or a combination thereof to determine a surface roughness value for different locations across the backside 110 surface. For example, changes in amplitude may indicate a peak or valley of the backside 110 and may be used to determine the period 204. In this instance, when the amplitude changes from lower to higher the location of that transition may be considered a valley and when the amplitude changes from high to lower, that location may be considered a peak. The distance between those changes in amplitude may be used to determine the period 204 or the frequency of the backside 110 surface features. The change in amplitude may be measured from an arbitrary reference point based on the initial contact with the substrate 106. The changes in amplitude may be given a positive or negative magnitude value based the direction that the profile sensor 116 moves following the initial contact. In another embodiment, the amplitude 204 scale may be based on a predetermined reference value. The amplitude 202 may be determined based on the movement of the profile sensor towards or away from this initial contact values or reference value. The lower amount of change over time or distance of the amplitude may indicate a lower surface roughness, wherein a relatively higher amount of change over time or distance may indicate a higher surface roughness value.

The texture map may be implemented several different ways using the amplitude 202 and period 204. The context or scale of these values may vary depending on the desired resolution of the texture map and the measurement capabilities of the location sensor 122 and the profile sensor 116. The instantaneous measurements may be used to generate the texture map based on the amplitude and the coordinates of where the surface roughness sample was taken.

In another embodiment, the texture map component 136 may determine surface roughness based a sample length or distance travelled by the profile sensor 116. One approach may be calculating the arithmetic average of the absolute values of the amplitude for a given length or distance. The given length or distance may be dependent upon the rotation speed of the substrate chuck 112 and the speed of the movement arm 118 as it moves across the substrate 106. The texture map component 136 may look for distance or lengths travelled by the profile sensor 116 and then average the amplitude data collected over that distance. Under another approach, the surface roughness may be measured using the root mean square average of the height differences over a given length or distance. In other instances, a person of ordinary skill in the art may use generally accepted surface roughness calculations as shown in any version of the American Society of Mechanical Engineers (ASME) Surface Texture standard B46.1.

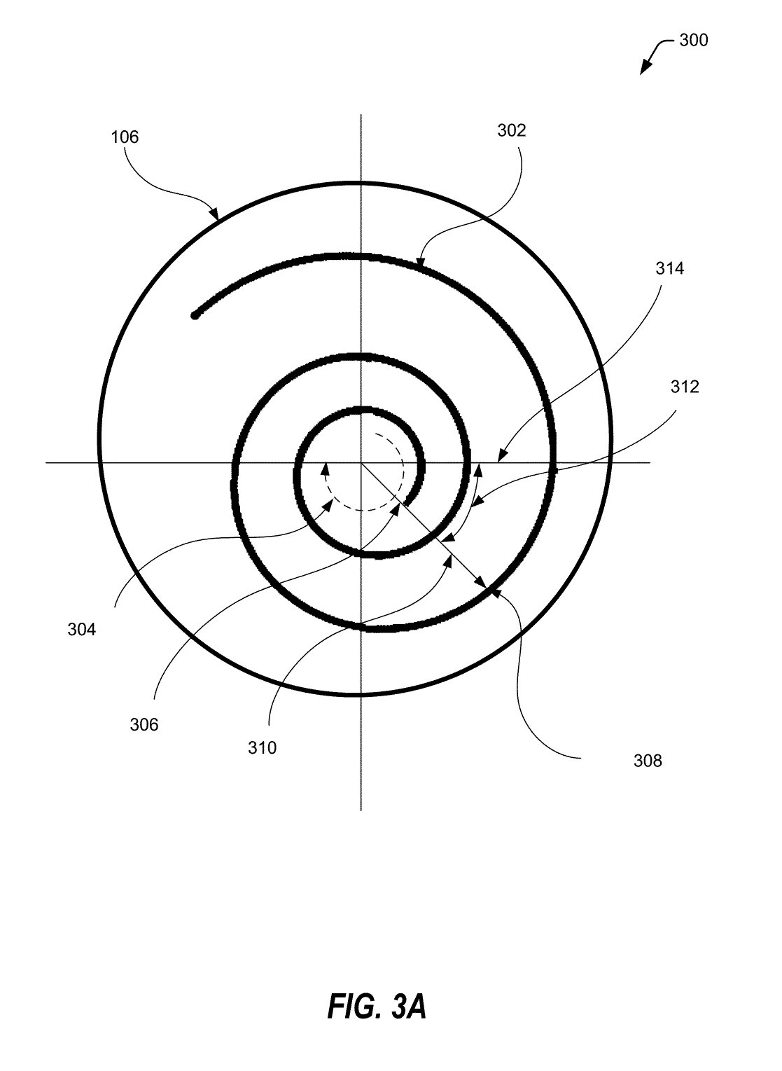

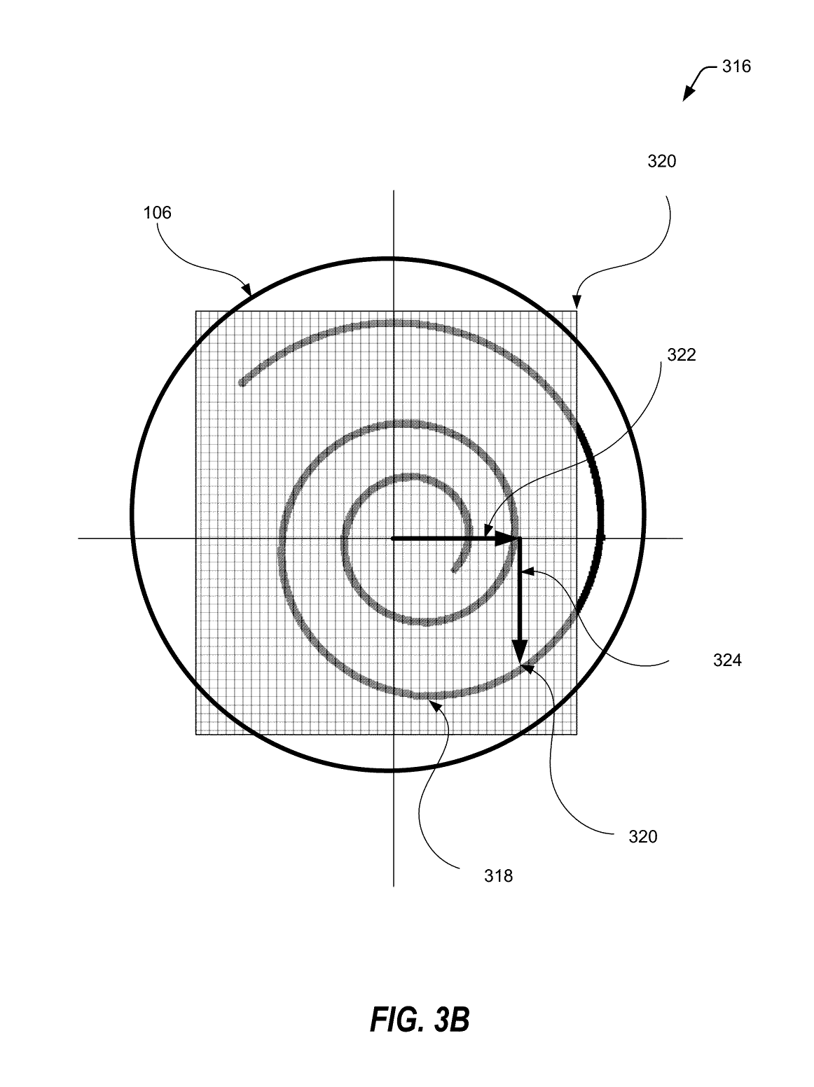

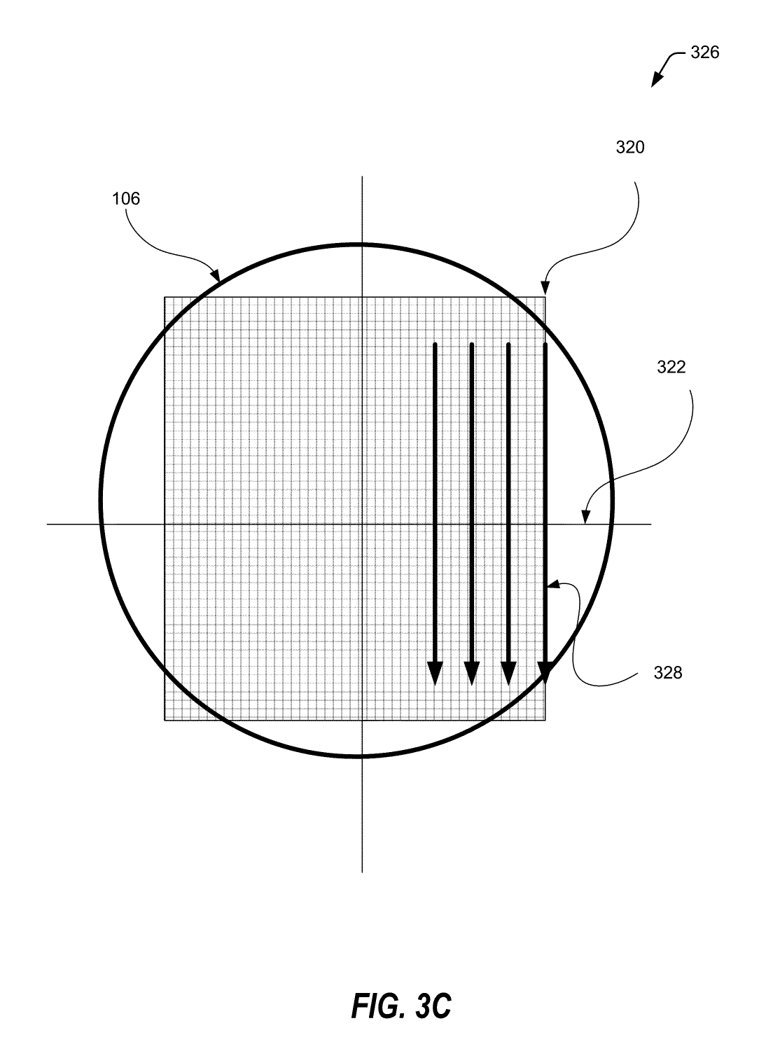

FIGS. 3A-3C are representative examples a profile sensor 116 path across the backside 110 surface of the substrate 106. For the purpose of ease of illustration and explanation, only a single path is shown in both examples, but the number of paths may vary depending on the number of profile sensors 116 used on the movement arm 118. The paths in FIGS. 3A & 3B are an indication of where the profile sensor 116 contacts or samples the backside 110 surface of the substrate 106. As noted above, the substrate 106 may be rotating while the profile sensor 116 may also be moving across the backside 106 surface. The profile sensor 116 movement may be linear or radial in nature. FIGS. 3A and 3B illustrate a bottom view of the substrate 106 from the perspective of a profile sensor 116 that scans the backside 110 surface. FIG. 3C illustrates a linear movement embodiment of the substrate 106 and/or profile sensors 116 across the backside 110 surface.

In other embodiments, multiple spiral paths may generated at the same time in contrast to the single spiral shown in FIGS. 3A & 3B. The multiple spiral paths may be offset from each other by the distance between profile sensors 116 coupled to the sensor arm. The profile sensors 116 may be spaced as close as a few millimeters apart.

FIG. 3A illustrates a bottom view 300 of the substrate 106 showing the sensor path 302 across the substrate 106 while the substrate 106 is rotating in a clockwise direction 304 and the profile sensor (not shown) is moving in a lateral/linear direction from the starting point 206 towards the edge of the substrate 106. In this embodiment, the location 208 of the profile senor 116 may be represented in polar coordinates using the radius(r) 210 from the center of the substrate 106 and the angle 212 (e.g, θ) from a reference line 314. In one embodiment, the reference lines 314 may aligned with an alignment notch (not shown) that is cut into the edge of the substrate 106 or scribe marks that may be etch into substrate 106.

The location component 132 may determine the radius starting location 306 based on the placement of the substrate 106 on the substrate chuck 112. The location sensors 122 may detect the edge of the substrate and the location component 132 may determine the position of the substrate 106 with respect to the substrate chuck 112 and the movement arm 118. The determination may be made using geometrical analysis techniques that are well known in the art. The location component 132, as needed, may convert the polar coordinates to Cartesian coordinates (e.g., x-y) using equations (1) and (2) below.

x=r cos θ (1)

y=r sin θ (2)

The location component 132 may convert the polar coordinates to x-y and then map them or convert them to front side 108 coordinates, if needed when the coordinate system axis references are different between the backside 110 and the front side 108 surfaces.

FIG. 3B illustrates a Cartesian coordinate system map 316 of the location of the profile sensor 116 across the substrate 106 along the sensor path 318 generated by rotating the substrate 106 and moving the profile sensor 116 laterally across the backside 110 surface. In contrast to the FIG. 3A embodiment, the system map 316 includes a Cartesian coordinate overlay template 320 to illustrate the x-y axis and the coordinates associated with the each portion of the sensor path 318. Particularly, a single contact point 320 was chosen to illustrate how the coordinates may be referenced by the location component 132. The contact point 320 may have an x-coordinate 322 and y-coordinate 324 that may be associated the profile sensor 116 collected at or near that location. If needed, the location component 132 may convert the backside 110 coordinate information to front side 108 coordinates.

Particularly, a single contact point 320 was chosen to illustrate how the coordinates may be referenced by the location component 132. The contact point 320 may have an x-coordinate 322 and y-coordinate 324 that may be associated the profile sensor 116 collected at or near that location. If needed, the location component 132 may convert the backside 110 coordinate information to front side 108 coordinates. The combination of the location information and the profile information provides the capability to map the texture of the backside 110 surface. The map or table may be used to identify specific region(s) of the substrate 106 that may be targeted for process compensation on the front side 108 or additional backside 110 conditioning prior to the front side 108 processing. FIG. 3C illustrates a Cartesian coordinate system map 326 of the location of the profile sensor 116 across the substrate 106 along the sensor paths 328 generated by moving the profile sensor(s) 116 and/or the substrate 106 in a linear motion relative to each other. The profile sensors 116 may be arranged in a linear array side-by-side to extend across the substrate in a line as shown in the Cartesian coordinate overlay template 320 that illustrates portions of the sensor path 328. In one embodiment, the movement arm 118 may move across the substrate 106 in a horizontal manner in the x-y plane. Although the sensor path is shown to travel in the y-direction, the movement arm 118 is not limited to only that type of movement. Additional sensor paths (not shown) may also move in the x-direction or in any combination across the x-y plane. For example, the movement arm 118 may sweep along the y-direction across a portion of the substrate 106 in a different direction.

In another embodiment, a multi-array movement arm (not shown) may include columns and rows of profile sensors 116 that may cover a broader surface area than the movement arm 118 depicted in FIG. 1. In one specific embodiment, the multi-array embodiment may include profile sensors 116 that are aligned in a linear manner in the horizontal and vertical direction. In this way, the second and third rows of profile sensors 118 may cover the same area that was scanned by the first row. This may enable the texture map component 136 to validate or to optimize the texture data based on a larger data set of similar areas to reduce the error or variation in the profile sensors 116.

In another specific embodiment, the rows and/or columns of the multi-array movement arm (not shown) the profile sensors 116 may be arranged in an offset manner, such that subsequent rows or columns may cover a different surface area than the preceding row or column. However, the offset profile sensor 116 pattern may be duplicated to enable similar surface areas to be scanned again during a single movement of the multi-array movement arm. This may combine the ability to collect more data for the same or similar surface areas and cover a broader surface area in a single movement of the multi-array movement arm.

FIGS. 3A-3C are intended to merely illustrate exemplary embodiments of how texture map data may be collected and are not intended to limit the scope of the claims to these specific embodiments.

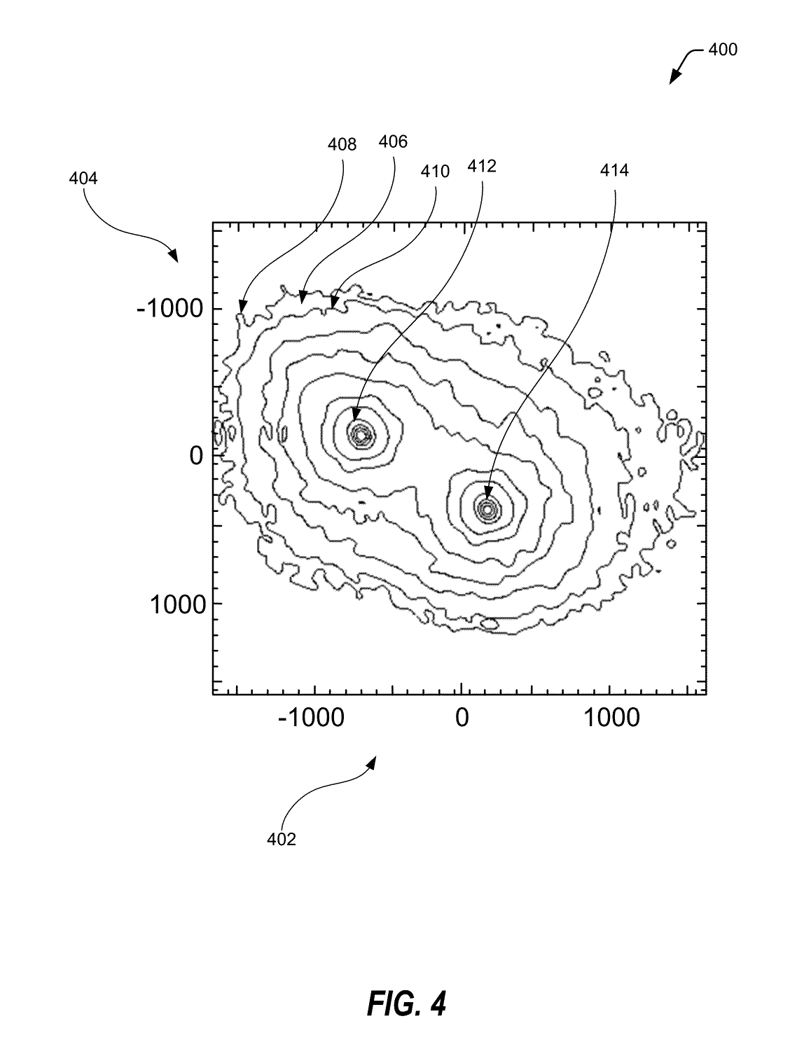

FIG. 4 illustrates an embodiment of a texture map 400 that highlights surface roughness values on a portion of the substrate 106. The texture map 400 in FIG. 4 is only for the purposes of explanation and the presentation of the surface roughness data may be presented or organized in any manner. This embodiment merely reflects one approach to communicating the location of surface roughness on the substrate 106. Hence, the x-axis 402 and the y-axis 404 are dimensionless and are not scaled to show the entire backside 110 surface.

The FIG. 4 embodiment illustrates a topographic map that uses contour lines to distinguish between different surface roughness values. The surface roughness values between the contour lines may be the same or may be within the some range of surface roughness values. For example, the outer contour region 406 between the first contour line 408 and the second contour line 410 may have the same surface roughness or within a discrete range of surface roughness throughout the region regardless of coordinate locations. The surface roughness at (−1500, 0) on the left side of the texture map 400 will have a similar value at (1300, 0) because both coordinate points are within the same outer contour region 406. The individual contour regions may be scaled to be higher or lower than the adjacent regions, typically the regions may be scaled from low to high but that configuration may not be required. The distance between the contour lines may also indicate the rate of change in values within that region. For example, when the contour lines are closer together this may indicate a higher rate of change than when the lines are a greater distance apart. An example of this may be shown in the center contour lines 412 that are closer together and may represent a peak or valley in surface roughness values. The center contour lines 412 show four contour lines that are much closer together than the adjacent regions. Hence, the rate of change in surface roughness, within the center contour line region 314, may be higher than the adjacent regions. The center contour lines 412 may represent the localized region described in the description of FIG. 1 that may cause the substrate 106 to bend or deform around that portion of the substrate 106. More broadly, the texture map 400 also illustrates that the rate of surface roughness change tends to be higher in the y-direction than in the x-direction. Hence, the adjustment component 138 may make more or larger adjustments to the patterning process when scanning in the y-direction than in the x-direction. However, this does not preclude adjustments being made in the x-direction. But, it does indicate that the changes made in the x-direction may be less frequent or may be smaller adjustments than when moving in the y-direction.

In certain instances, the texture map 400 regions may have similar surface roughness values, but they may not be adjacent to each other. However, these regions may be annotated (not shown) to indicate similar values within those regions. The annotations may include letters, numbers, colors, texture figures, or a combination thereof to indicate similarity to non-adjacent contour regions. For example, the second contour region 414 may have similar surface roughness values to the center contour line 412 region. The aforementioned annotations may be used in other similar regions (not shown) throughout the texture map 400.

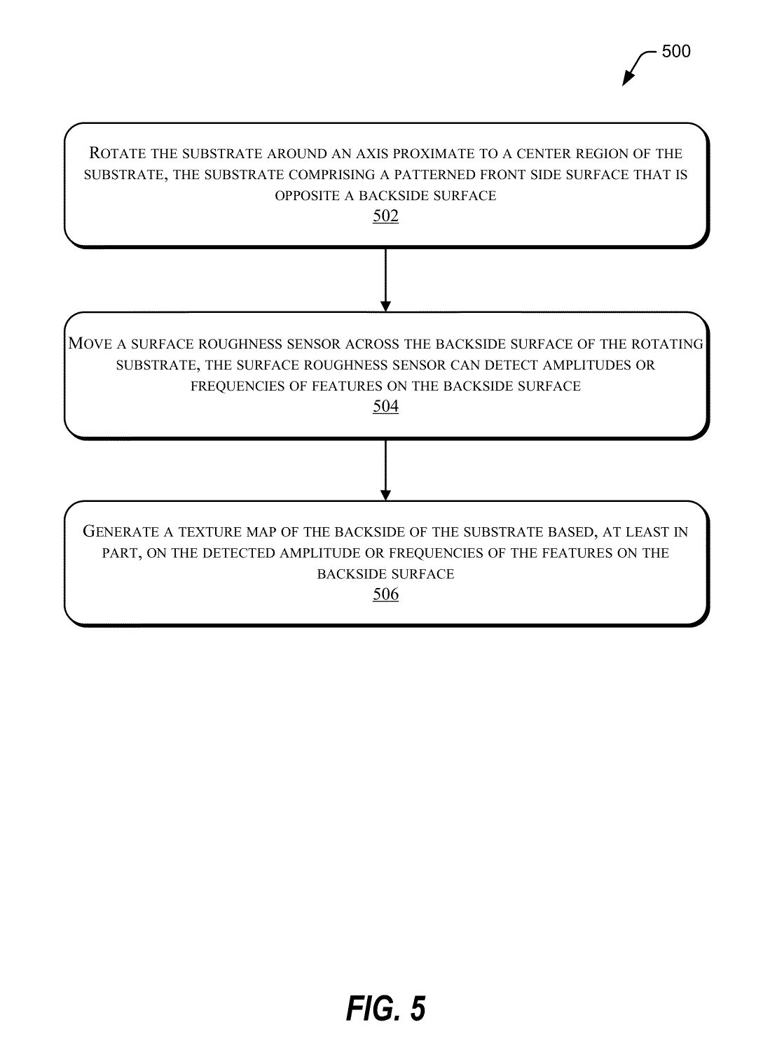

FIG. 5 illustrates a flow diagram for method 500 for using the texture mapping system 100 to capture and collect surface roughness data of the backside 110 of the substrate 106. The surface roughness data may be used to adjust subsequent processing conditions (e.g., patterning, backside 110 conditioning) to eliminate or minimize the impact backside 110 surface conditions. The surface roughness detection may occur when the substrate 106 is secured to a substrate chuck 112 using the backside 110 surface. This configuration prevents direct contact with the front side 108 surface or the electronic devices being manufactured on the front side 108 surface. The backside 110 technique enables non-destructive testing for surface roughness, which enables feed forward control for subsequent processes. The texture mapping system 110 may be integrated with the processing chamber that may include the substrate chuck 112, the profile sensors 116, and a movement arm 118 to position the profile sensors 116 against the backside 110 surface. The illustrated method 500 is merely one embodiment and persons or ordinary skill in the art may add additional operations, omit one or more of the operations, or perform the operations in a different order.

At block 502, the incoming substrate 106 may be secured to the substrate chuck 112 using mechanical, pneumatic, or electrical coupling techniques via the backside 110 surface. The substrate chuck 112 may not contact the front side 108 surface to avoid damaging the patterns or electrical devices that may be present on the front side 108. The movement component 130 may direct the substrate chuck to rotate around an axis that is proximate to a center or center region of the substrate 106. The orientation of the substrate 106 and the rotation speed may be optimized to prevent or minimize substrate 106 vibrations. In one embodiment, the rotation speed may be between 30 rpm and 60 rpm.

The substrate 106 may be aligned prior to entering the process chamber 104. Typically, the alignment may be done using a scribe mark or notch that is incorporated into the substrate 106. The alignment may provide a consistent reference for coordinate information collected or calculated during the surface roughness scanning. In some instances, the substrate 106 alignment may be done in the process chamber 104. For example, the substrate 106 may be rotated to a certain position to confirm the alignment prior to surface roughness scanning.

At block 504, the surface roughness scanning may begin by moving a surface roughness sensor (e.g., profile sensor(s) 116) across the backside 110 surface of the rotating substrate 106. The surface roughness sensor may detect amplitudes and/or frequencies of features on the backside 110 surface of the substrate 106. The surface roughness sensor may use mechanical, electrical, optical, or combination thereof to detect the characteristics of the backside 110 features. In one embodiment, the surface roughness sensor may include a contact element that is placed in physical contact with the backside 110 surface, as shown in FIG. 2. The movement arm 118 may be positioned to initiate that contact before or after the substrate begins to rotate. The vibrations generated as a result of the contact element moving across the backside 110 surface may be converted into a profile signal (e.g., electrical signal) using the detection component (e.g., piezoelectric transducer) that may be coupled to the contact element. The profile signal may be an electrical representation of the amplitude and/or frequencies of the backside 110 surface features. The amplitude may provide an indication of the peak-to-valley profile of the backside 110 features and may provide an indication of the height of the features. The period or frequency (e.g., 1/period) of the features may provide an indication of how far apart or how wide the features may be within the scanned area. However, the location of the backside 110 features may also be important to guide feed forward control for subsequent processing.

The location component 132 may also be monitoring the location of the movement arm 118, the substrate 106, and the profile sensor(s) 116 that detect or collect the surface roughness data. The locations may be determined by using the location sensors 122 and/or by using well known geometrical analysis techniques based on the geometry of the moving components and the types of movements being made by those components.

In one embodiment, the movement arm 118 may be moving in a linear movement across the backside surface. The linear movement may be moving back and forth within the same plane. However, the movement arm 118 may not be limited only to linear movement. In another embodiment, the movement arm 118 may be moving radially, such that the movement arm sweeps across the backside 110 surface by pivoting around a fix point of the movement arm 118. The radial movement may be similar to a record player arm that may move a needle across the record. The location component 132 may determine the location of the backside 100 contact given the known position of the substrate 106 and the movement arm 118 as it moves across the backside 110 of the substrate 106.

The location component 132 may assign a location to discrete portions of the profile signal generated by or stored in the signal component 134. The location or coordinate information may be used to determine the relative position of the substrate 106 and the profile sensor(s) 116. The combination of the profile signal and the location signal may provide a marker or tag that may be used to assemble a texture map of the backside 110 surface.

At block 506, the texture map component 136 may use a computer processor 126 to generate a texture map or table of the backside 110 of the substrate 106 based, at least in part, on the detected amplitude and/or frequencies of the features on the backside surface and the location information assigned to discrete portions of those characteristics. The discrete portions may include instantaneous readings of amplitude and/or frequency or a small duration (e.g., time or distance) of the amplitude and/or frequency readings. The locations may operate as a tag that enables the texture map component to determine the orientation of the portions with respect to each other. For example, the location information may be used to stich or group together discrete portions to an organized way, such that the information forms a representation of the surface roughness across the backside 110 surface of the substrate 106.

The combination of the discrete portions may be used to form a texture map or table that may be used to visualize and/or analyze the data by a computer or by a person. The texture map may provide an indication of the surface roughness at discrete locations of the backside of the substrate 106. In one embodiment, the texture map may be, but is not limited to, a contour map as shown in FIG. 4.

The texture map or table may have a high enough resolution to adjust processing conditions for subsequent substrate 106 processing at specific sites that may correspond to positions on the texture map or table. In one embodiment, the texture map may be provided to the adjustment component 138 that may determine which portions of the front side 108 surface may be candidates for process changes to minimize the impact of backside 110 surface roughness on front side 108 processing. If needed, the texture mapping system 100 may correlate backside 110 locations to front side 108 locations. In one embodiment, the adjustments may include, but are not limited to, depth of focus adjustments (e.g., z-direction) and/or overlay adjustments (e.g., x-direction, y-direction) that may be used to compensate for variations of front side 108 topography that may be caused by backside 110 surface roughness.

It should be understood that the foregoing description is only illustrative of the invention. Various alternatives and modifications can be devised by those skilled in the art without departing from the invention. Accordingly, the present invention is intended to embrace all such alternatives, modifications and variances that fall within the scope of the appended claims.

What is claimed is:

1. A texture mapping system, comprising:
a substrate chuck that can rotate a substrate around an axis, the substrate comprising a patterned front side surface that is opposite a backside surface;
a profile sensor that can move across the backside surface of the substrate and generate a profile signal based, at least in part, on surface roughness on the backside surface of the substrate;
a location controller that can generate a location signal based, at least in part, on locations of the profile sensor relative to the substrate; and
a texture map component that can generate a texture map of the backside of the substrate based, at least in part, on the profile signal and the location signal, the texture map comprising an indication of surface roughness at locations on the backside of the substrate.

2. The system of claim 1, wherein the profile sensor comprises:
a contact element that can make contact with the backside surface of the substrate; and
a detection component coupled to the contact element, the detection component can generate the profile signal when pressure or a force is applied to the contact element.

3. The system of claim 1, wherein the surface roughness is based, at least in part, on a plurality of amplitudes of the backside surface of the substrate.

4. The system of claim 1, wherein the surface roughness is based, at least in part, on a plurality of amplitudes and periods of the backside features.

5. The system of claim 1, wherein the profile sensor comprises two or more contact elements that can make contact with the backside surface at different locations and the contact elements being coupled to corresponding detection components that generate the profile signal for the contact elements.

6. The system of claim 5, wherein the texture map processor generates the texture map based, at least in part, on a combination of the profile signals from the two or more contact elements.

7. The system of claim 6, wherein the texture map processor generates the texture map based, at least in part, on a combination of the location signals from two or more contact elements.

8. The system of claim 1, wherein the substrate chuck can rotate at no more than 60 revolutions per minute.

9. The system of claim 1, further comprising a movement arm that can move the profile sensor across the backside of the substrate.

10. The system of claim 1, further comprising a movement arm coupled to the profile sensor, the sensor arm can move the profile sensor to make contact with the backside surface of the substrate.

11. A method for mapping surface roughness of a substrate, comprising:
rotating, using a substrate chuck, the substrate around an axis proximate to a center region of the substrate, the substrate comprising a patterned front side surface that is opposite a backside surface;
moving a surface roughness sensor across the backside surface of the rotating substrate, the surface roughness sensor can detect amplitudes or frequencies of features on the backside surface; and
generating, using a computer processor, a texture map of the backside of the substrate based, at least in part, on the detected amplitude or frequencies of the features on the backside surface.

12. The method of claim 11, wherein the texture map comprises coordinate information of where the surface roughness sensor contacted the substrate and the amplitude or frequency of the features at or near the coordinate information.

13. The method of claim 11, further comprising:
generating, using the surface roughness sensor, a profile signal based, at least in part, on the detected amplitudes or frequencies of the features of the backside of the substrate; and
generating, using a location sensor, a location signal based, at least in part, on locations of where the surface roughness sensor detected the amplitudes or frequencies of the features of the backside of the substrate.

14. The method of claim 11, wherein the texture map provides an indication of surface roughness at locations of the backside of the substrate.

15. The method of claim 11, wherein the location signal comprises coordinate information based, at least in part, on radial movement of the substrate and linear movement of the profile sensor.

16. The method of claim 15, wherein the texture map comprises a contour plot of surface roughness of the backside surface.

17. The method of claim 11, further comprising providing the texture map to an adjustment component that can correlate backside coordinate locations of the texture map to front side coordinate locations and determine offset adjustments for the front side coordinate locations.

18. The method of claim 17, wherein the offset adjustments comprise a depth of focus adjustment value that corresponds to at least one of the coordinates and surface roughness values.

19. The method of claim 17, wherein the rotating comprises a rotation speed between 5 revolutions per minute (rpm) and 60 rpm.

20. A system, comprising:
a process chamber that can process semiconductor substrates comprising a front side surface that is opposite a backside surface;
a substrate chuck disposed within the process chamber that contacts the backside surface when the substrate is in the process chamber;
a surface roughness detector that can detect surface roughness of the backside surface when the substrate is in the process chamber.
